(19) United States
(12) Patent Application Publication
(10) Pub. No.: US 2013/0307606 A1
(43) Pub. Date: Nov. 21, 2013

(54) SUPER HIGH VOLTAGE DEVICE AND METHOD FOR OPERATING A SUPER HIGH VOLTAGE DEVICE

(71) Applicant: LEADTREND TECHNOLOGY CORP., Hsin-Chu (TW)

(72) Inventors: Chi-Pin Chen, Hsin-Chu (TW); Yung-Hao Lin, Hsin-Chu (TW); Ming-Nan Chuang, Hsin-Chu (TW); Ming-Ying Kuo, Hsin-Chu (TW)

(73) Assignee: Leadtrend Technology Corp., Hsin-Chu (TW)

(21) Appl. No.: 13/798,190

(22) Filed: Mar. 13, 2013

(30) Foreign Application Priority Data
May 18, 2012 (TW) 101117842

(51) Int. Cl. H01L 29/78; H03K 3/012

(52) U.S. Cl. CPC H01L 29/7832; H03K 3/012
USPC 327/379; 257/262

(57) ABSTRACT

A super high voltage device includes a first gate, a second gate, a drain, a first source, a second source, and a third source. The first gate is used for receiving a first control signal generated from a pulse width modulation controller. The second gate is used for receiving a second control signal generated from the pulse width modulation controller. The drain is used for receiving an input voltage. First current flowing from the drain to the first source varies with the first control signal and the input voltage. The second control signal is used for controlling turning-on and turning-off of second current flowing from the drain to the second source and third current flowing from the drain to the third source. The third source is proportional to the second current.

### BACKGROUND OF THE INVENTION

1. Field of the Invention

The present invention relates to a super high voltage device and a method of operating a super high voltage device, and particularly to a super high voltage device and a method of operating a super high voltage device that can provide a high voltage startup function and reduce power loss of the super high voltage device.

2. Description of the Prior Art

In an application of a power convertor, a power switch of the power convertor is controlled by a controller (e.g. a pulse width modulation controller) to determine a duty ratio or a duty time of the power switch to control store power or release power of a power storage device (e.g. an inductor) in series with the power switch and further convert an input power into an output voltage. Therefore, the power switch is inevitably connected to a high voltage input power for a high voltage application, resulting in the power switch for the high voltage application needing a particular process to increase high voltage capability thereof.

In the prior art, the controller is mainly composed of integrated circuits. If the controller composed of the integrated circuits is directly connected to a high voltage input power, cost thereof may be increased based on consideration of a chip area. Thereof, how to efficiently integrate a device for receiving a high voltage power or a high voltage signal with a controller is an important target of an integrated circuit design house presently.

### SUMMARY OF THE INVENTION

An embodiment provides a super high voltage device. The super high voltage device includes a first gate, a second gate, a drain, a first source, a second source, and a third source. The first gate is used for receiving a first control signal generated from a pulse width modulation controller. The second gate is used for receiving a second control signal generated from the pulse width modulation controller. The drain is used for receiving an input voltage. First current flowing from the drain to the first source varies with the first control signal and the input voltage, the second control signal is used for controlling turning-on and turning-off of second current flowing from the drain to the second source and third current flowing from the drain to the third source, wherein the third current is proportional to the second current.

Another embodiment provides a super high voltage device. The super high voltage device includes a substrate having a first conductivity type, a first doped well having a second conductivity type, a drain having the second conductivity type, a second doped well having the first conductivity type, a first source having the second conductivity type, a first field oxide, a first gate, a second gate, a second source having the second conductivity type, a third source having the second conductivity type, and a base having the first conductivity type. The first doped well is formed on the substrate and has an extension portion. The drain is formed on the first doped well, and ion concentration of the drain is higher than ion concentration of the first doped well. The second doped well surrounds the first doped well outside the extension portion, and is formed on the substrate. The first source is formed on the extension portion, and ion concentration of the first source is higher than ion concentration of the first doped well. The first field oxide is formed on the first doped well outside the first source, the drain, and the second doped well. The first gate is formed between the drain and first source, and being located on the first field oxide. The second gate is formed partially on the first field oxide of the first doped well and formed partially on the second doped well. The second source is formed on the second doped well, and ion concentration of the second source is higher than ion concentration of the second doped well. The third source is formed on the second doped well, and ion concentration of the third source is higher than ion concentration of the second doped well. The base is formed on the second doped well, and ion concentration of the base is higher than ion concentration of the second doped well.

Another embodiment provides a method of operating a super high voltage device, wherein the super high voltage device includes a first gate, a second gate, a drain, a first source, a second source, and a third source. The method includes receiving an input voltage; providing first current, wherein the first current flows from the drain to the first source; receiving a first control signal generated from a pulse width modulation controller; turning off the first current according to the first control signal; receiving a second control signal generated from the pulse width modulation controller; and controlling turning-on and turning-off of second current flowing from the drain to the second source and third current flowing from the drain to the third source according to the second control signal.

The present invention provides a super high voltage device and a method of operating a super high voltage device. The super high voltage device and the method utilize a junction field effect transistor of the super high voltage device to generate startup current of a pulse width modulation controller according to an input voltage. After the pulse width modulation controller is started up, the pulse width modulation controller can generate a second control signal to the super high voltage device according to third current flowing through a current detection unit of the super high voltage device. Then, a power switch of the super high voltage device can turn on and turn off second current flowing through the power switch of the super high voltage device according to the second control signal, and the current detection unit can turn on and turn off third current flowing through the current detection unit of the super high voltage device according to the second control signal because the third current is proportional to the second current. Therefore, compared to the prior art, the present invention has advantages as follows: first, because the super high voltage device is integrated with a high voltage startup function a clock control chip having a requirement of the high voltage startup function does not need to be taped out to a fabrication plant for semiconductor manufacture having a super high voltage process; second, because the power switch of the super high voltage device has a low conductor impedance, the present invention can reduce conduction loss and heat generation of the super high voltage device; third, because the second current flowing through the power switch of the super high voltage device does not flow through the current detection unit of the super high voltage device, negative voltage effect and noise generated by a parasitic inductor of the current detection unit and power loss of the current detection unit can be significantly reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a diagram illustrating a super high voltage device according to an embodiment.

FIG. 2 is a diagram illustrating the pulse width modulation controller utilizing a sensing resistor to sense the third current flowing through the current detection unit.

FIG. 3 is a diagram illustrating a super high voltage device according to another embodiment.

FIG. 4 is a diagram illustrating a cross section I of the super high voltage device.

FIG. 5 is a diagram illustrating a cross section II of the super high voltage device.

FIG. 6 is a diagram illustrating a cross section III of the super high voltage device.

FIG. 7 is a flowchart illustrating method of operating a super high voltage device according to another embodiment.

### DETAILED DESCRIPTION

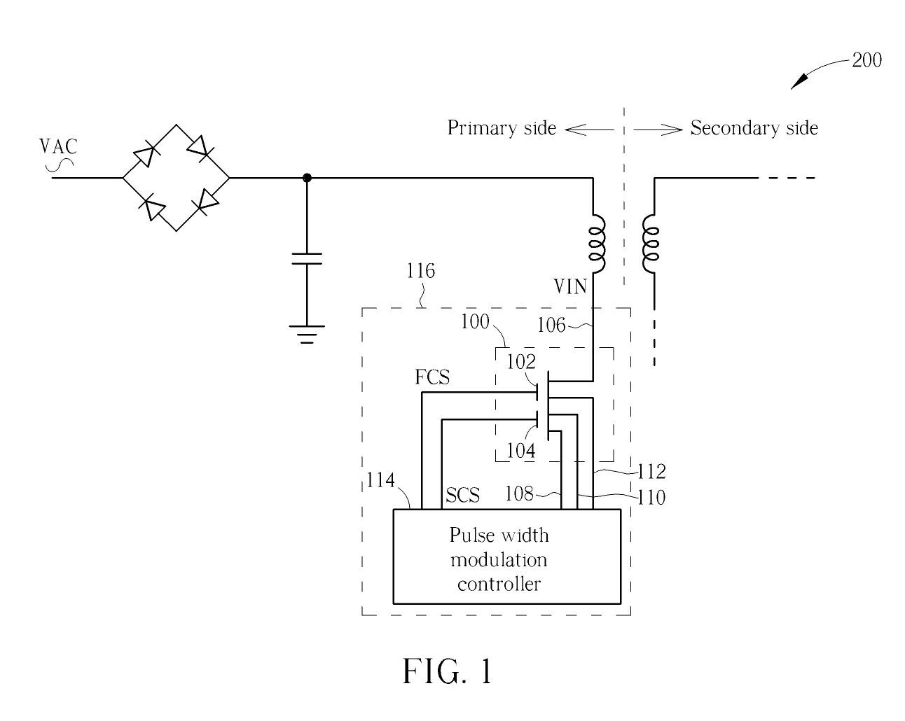

Please refer to FIG. 1. FIG. 1 is a diagram illustrating a super high voltage device 100 according to an embodiment. As shown in FIG. 1, the super high voltage device 100 includes a first gate 102, a second gate 104, a drain 106, a first source 108, a second source 110, and a third source 112. The first gate 102 is used for receiving a first control signal FCS generated from a pulse width modulation controller 114. The second gate 104 is used for receiving a second control signal SCS generated from the pulse width modulation controller 114, where thickness of the first gate 102 is the same as thickness of the second gate 104, or the thickness of the first gate 102 is greater than the thickness of the second gate 104. The drain 106 is used for receiving an input voltage VIN, where the input voltage VIN is generated by a primary side of a power conversion circuit 200 according to an alternating current voltage VAC. As shown in FIG. 1, the first gate 102, the drain 106, and the first source 108 are a junction field effect transistor (JFET). The second gate 104, the drain 106, and the second source 110 are a power switch. The second gate 104, the drain 106, and the third source 112 are a current detection unit. But, in another embodiment of the present invention, the first gate 102, the drain 106, and the first source 108 can be also a depletion type field effect transistor, a composite structure composed of a junction field effect transistor and a metal-oxide-semiconductor field effect transistor (MOSFET), or a composite structure composed of a depletion type field effect transistor and a metal-oxide-semiconductor field effect transistor. As shown in FIG. 1, the super high voltage device 100 can provide a first current to the pulse width modulation controller 114 to start up the pulse width modulation controller 114 before a voltage between the first gate 102 and the first source 108 is not equal to a pinch-off voltage (that is, the first current acts as startup current of the pulse width modulation controller 114). That is to say, during the power conversion circuit 200 being started up, the power conversion circuit 200 can generate the input voltage VIN having a super high voltage level according to the alternating current voltage VAC. Meanwhile, the super high voltage device 100 can provide the first current to the pulse width modulation controller 114 to start up the pulse width modulation controller 114 according to the input voltage VIN having the super high voltage level. After the pulse width modulation controller 114 is started up, the pulse width modulation controller 114 can generate the first control signal FCS to the first gate 102. Then, the super high voltage device 100 can turn off the first current according to the first control signal FCS. That is to say, after the pulse width modulation controller 114 is started up, the junction field effect transistor is turned off to reduce power consumption of the super high voltage device 100 when the voltage between the first gate 102 and the first source 108 is equal to the pinch-off voltage. In addition, in another embodiment of the present invention, the first gate 102 can be coupled to ground. Therefore, the pulse width modulation controller 114 can turn off the first current by adjusting a voltage of the first source 108. The power switch composed of the second gate 104, the drain 106, and the second source 110 turns on or turns off the primary side of the power conversion circuit 200 according to the second control signal SCS, where the power switch composed of the second gate 104, the drain 106, and the second source 110 has a low conductor impedance, so the power switch can reduce conduction loss and heat generation. As shown in FIG. 1, the current detection unit composed of the second gate 104, the drain 106, and the third source 112 is used for detecting a second current (that is, a current flowing from the drain 106 to the second source 110) flowing through the power switch through a third current (that is, a current flowing from the drain 106 to the third source 112) flowing through the current detection unit, where because the third current is proportional to the second current, the current detection unit can detect the second current according to the third current.

After the pulse width modulation controller 114 is started up, the pulse width modulation controller 114 can generate the second control signal SCS, where the second control signal SCS is a pulse width modulation signal. When a voltage of the second control signal SCS is higher than a threshold voltage, the power switch and the current detection unit are turned on, resulting in the second current flowing from the drain 106 to the second source 110 and the third current flowing from the drain 106 to the third source 112; when the voltage of the second control signal SCS is lower than the threshold voltage, the power switch and the current detection unit are turned off. Because the third current is proportional to the second current, the pulse width modulation controller 114 can generate the second control signal SCS according to the third current to control turning-on and turning-off of the third current and the second current. As shown in FIG. 1, the super high voltage device 100 can be integrated with the pulse width modulation controller 114 in the same packet 116, where the super high voltage device 100 and the pulse width modulation controller 114 can be installed on the same lead frame or different lead frames. In addition, in another embodiment of the present invention, the super high voltage device 100 can be integrated with the pulse width modulation controller 114 in the same chip. In addition, in another embodiment of the present invention, the super high voltage device 100 is an independent packed device.

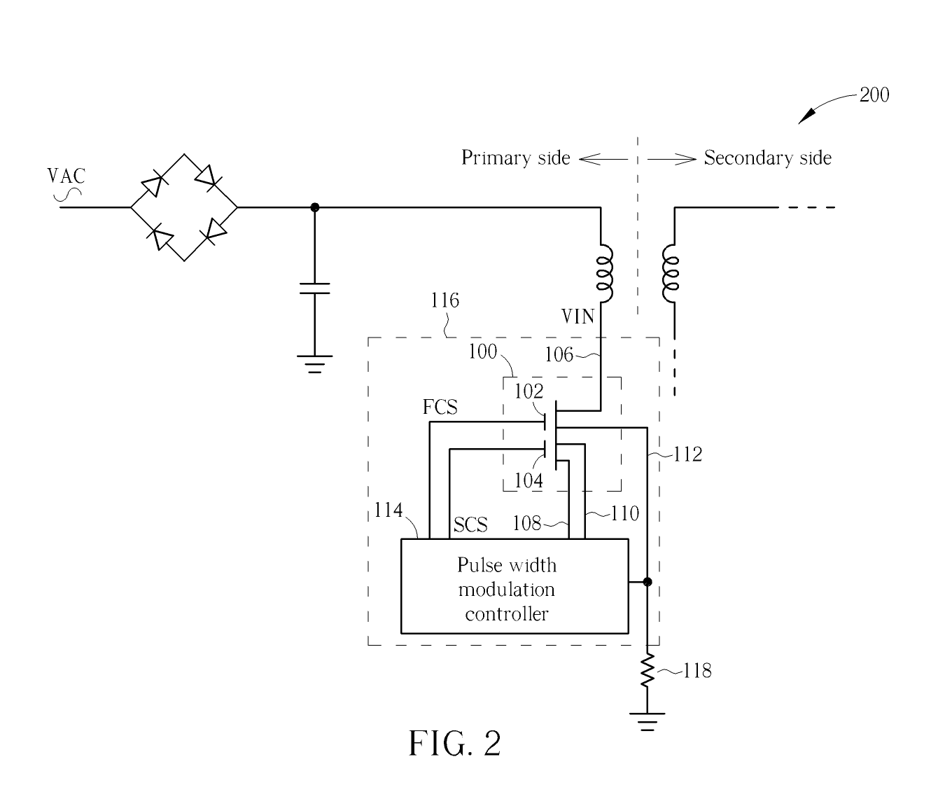

Please refer to FIG. 2. FIG. 2 is a diagram illustrating the pulse width modulation controller 114 utilizing a sensing resistor 118 to sense the third current flowing through the current detection unit. As shown in FIG. 2, a user can connect the sensing resistor 118 to the third source 112 of the super high voltage device 100 in series. Therefore, the pulse width modulation controller 114 can know the third current flowing through the current detection unit and the second current flowing through the power switch according to a voltage drop of the sensing resistor 118. In addition, a detection method in FIG. 2 is usually a low voltage detection mode due to consideration of power loss.

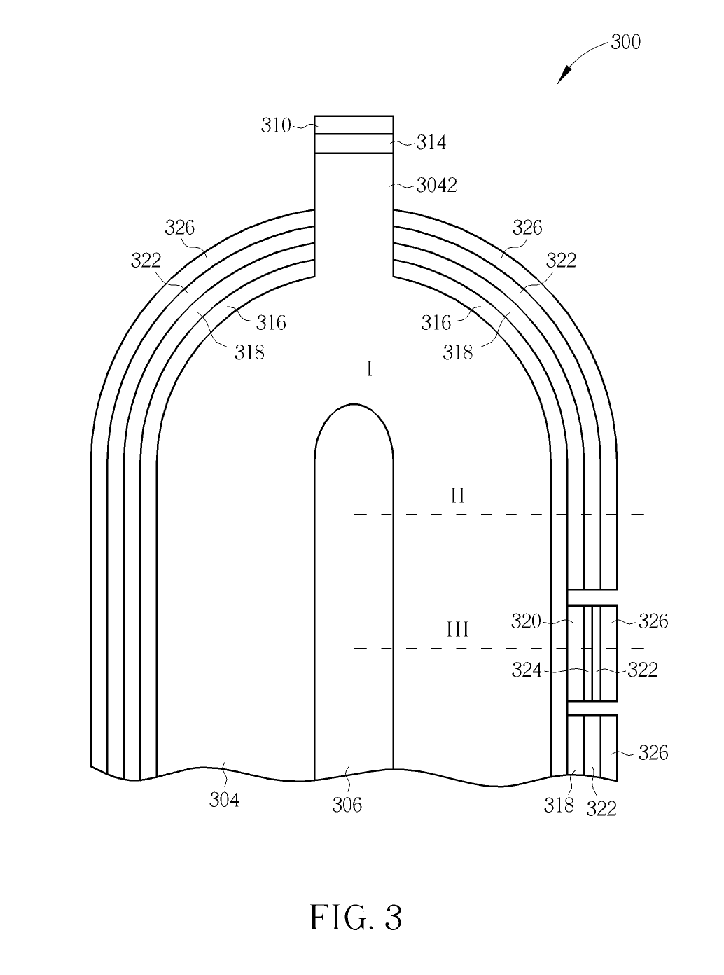

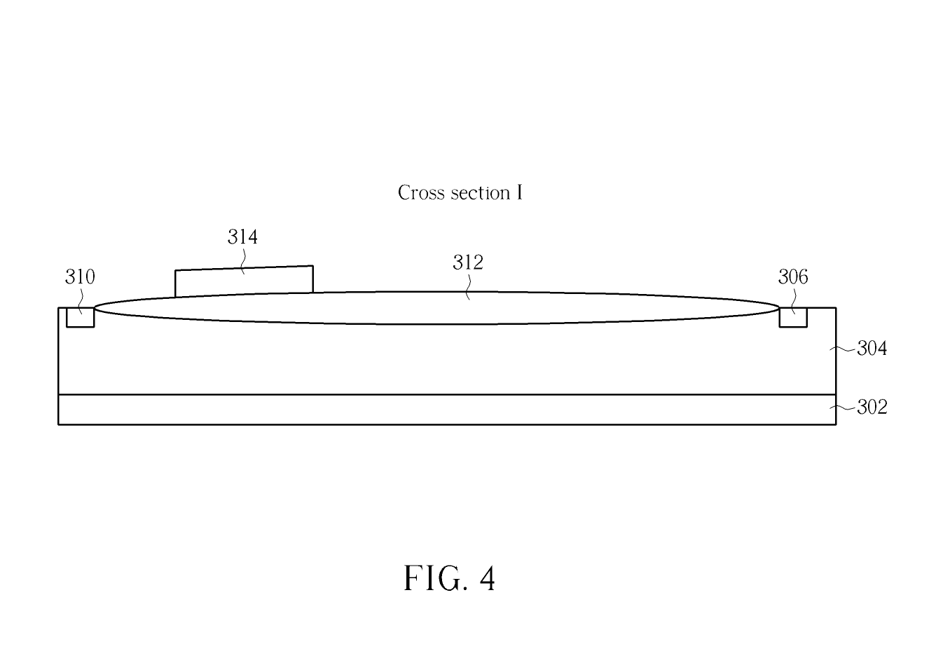

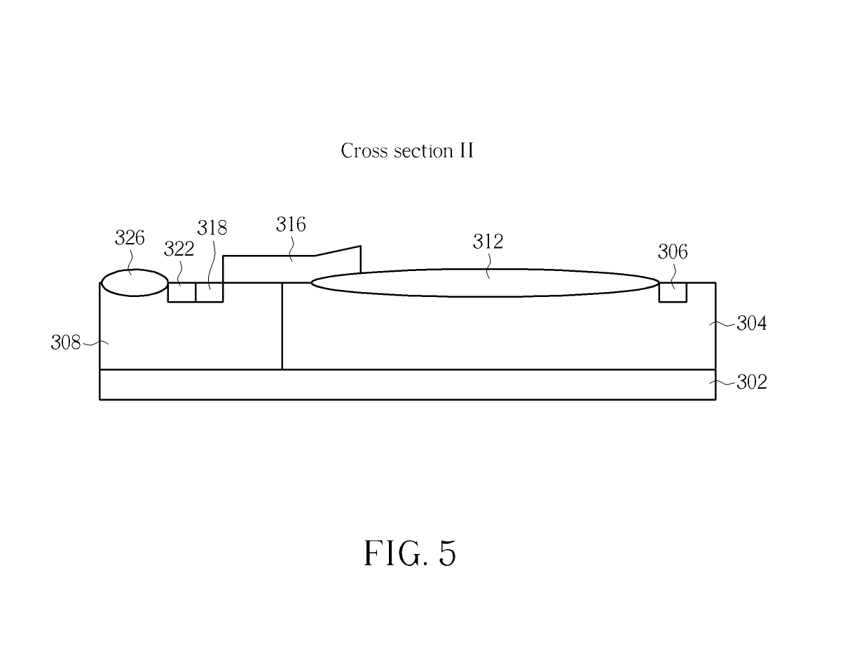

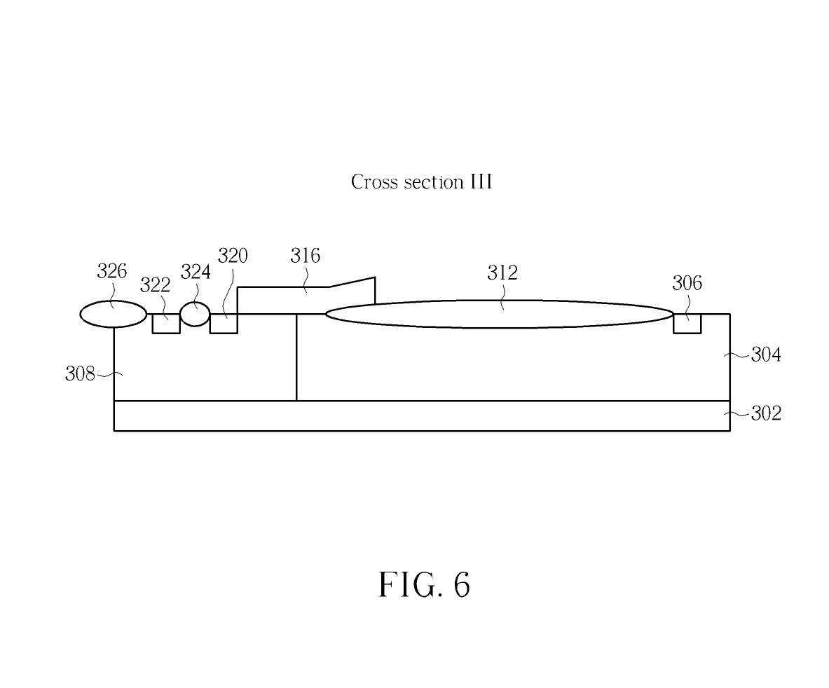

Please refer to FIG. 3, FIG. 4, FIG. 5, and FIG. 6. FIG. 3 is a diagram illustrating a super high voltage device 300 according to another embodiment, FIG. 4 is a diagram illustrating a cross section I of the super high voltage device 300, FIG. 5 is a diagram illustrating a cross section II of the super high voltage device 300, and FIG. 6 is a diagram illustrating a cross section III of the super high voltage device 300. The super high voltage device 300 includes a substrate 302 having a first conductivity type, a first doped well 304 having a second conductivity type, a drain 306 having the second conductivity type, a second doped well 308 having the first conductivity type, a first source 310 having the second conductivity type, a first field oxide 312, a first gate 314, a second gate 316, a second source 318 having the second conductivity type, a third source 320 having the second conductivity type, a base 322 having the first conductivity type, a second field oxide 324, and a third field oxide 326, where the first conductivity type is P type and the second conductivity type is N type. But, in another embodiment of the present invention, the first conductivity type is N type and the second conductivity type is P type. In addition, the first doped well 304, the drain 306, the second doped well 308, the first source 310, the second source 318, the third source 320, and the base 322 are formed by a photolithigraphy process and ion implantation. In addition, the first field oxide 312, the second field oxide 324, and the third field oxide 326 are field oxides fabricated by a Local Oxidation of Silicon (LOCOS). As shown in FIG. 3, FIG. 4, FIG. 5, and FIG. 6, the first doped well 304 is formed on the substrate 302 and has an extension portion 3042, where the substrate 302, the first field oxide 312, and the second doped well 308 are not shown in FIG. 3, and the drain 306, the first source 310, and the extension portion 3042 are located at the same axis. The drain 306 is formed on the first doped well 304, and ion concentration of the drain 306 is higher than ion concentration of the first doped well 304. As shown in FIG. 5 and FIG. 6, the second doped well 308 surrounds the first doped well 304 outside the extension portion 3042, and is formed on the substrate 302. As shown in FIG. 3 and FIG. 4, the first source 310 is formed on the extension portion 3042, and ion concentration of the first source 310 is higher than the ion concentration of the first doped well 304. As shown in FIG. 4, FIG. 5, and FIG. 6, the first field oxide 312 is formed on the first doped well 304 outside the first source 310, the drain 306, and the second doped well 308. As shown in FIG. 3 and FIG. 4, the first gate 314 is formed between the drain 306 and the first source 310, and is located on the first field oxide 312. As shown in FIG. 3, FIG. 5, and FIG. 6, the second gate 316 is formed partially on the first field oxide 312 of the first doped well 304, and the second gate 316 is formed partially on the second doped well 308. As shown in FIG. 3 and FIG. 5, the second source 318 is formed on the second doped well 308, and ion concentration of the second source 318 is higher than the ion concentration of the second doped well 308. As shown in FIG. 3 and FIG. 6, the third source 320 is formed on the second doped well 308, and ion concentration of the third source 320 is higher than the ion concentration of the second doped well 308. As shown in FIG. 3, FIG. 5, and FIG. 6, the base 322 is formed on the second doped well 308 for receiving a base voltage, and ion concentration of the base 322 is higher than ion concentration of the second doped well 308. As shown in FIG. 3 and FIG. 6, the second field oxide 324 is formed on the second doped well 308 between the third source 320 and the base 322. As shown in FIG. 3, FIG. 5, and FIG. 6, the third field oxide 326 is formed on the second doped well 308 of a side of the base 322. In addition, the first gate 314 and the second gate 316 are polysilicon gates, and thickness of the first gate 314 is the same as thickness of the second gate 316. But, in another embodiment of the present invention, the thickness of the first gate 314 is greater than the thickness of the second gate 316. In addition, as shown in FIG. 5, the second source 318 is adjacent to the base 322; and as shown in FIG. 6, the second field oxide 324 is blocked the third source 320 and the base 322.

As shown in FIG. 3 and FIG. 4, the first gate 314, the drain 306, and the first source 310 are a junction field effect transistor. But, in another embodiment of the present invention, the first gate 314, the drain 306, and the first source 310 can be also a depletion type field effect transistor, a composite structure composed of a junction field effect transistor and a metal-oxide-semiconductor field effect transistor, or a composite structure composed of a depletion type field effect transistor and a metal-oxide-semiconductor field effect transistor. When the power conversion circuit 200 (as shown in FIG. 1) is started up, the power conversion circuit 200 can generate the input voltage VIN having the super high voltage level according to the alternating current voltage VAC, where the drain 306 is used for receiving the input voltage VIN having the super high voltage level. Meanwhile, the junction field effect transistor provides a first current to the pulse width modulation controller 114 (as shown in FIG. 1) according to the input voltage VIN having the super high voltage level to start up the pulse width modulation controller 114. After the pulse width modulation controller 114 is started up, the pulse width modulation controller 114 can generate the first control signal FCS (as shown in FIG. 1) to the first gate 314. Then, the super high voltage device 300 can turnoff the first current according to the first control signal FCS. That is to say, after the pulse width modulation controller 114 is started up, the junction field effect transistor is turned off to reduce power consumption of the super high voltage device 300 when a voltage between the first gate 314 and the first source 310 is equal to the pinch-off voltage.

As shown in FIG. 3, FIG. 5, and FIG. 6, the second gate 316, the drain 306, and the second source 318 are a power switch; and the second gate 316, the drain 306, and the third source 320 are a current detection unit. As shown in FIG. 3, FIG. 5, and FIG. 6, the power switch and the current detection unit share the second gate 316 and the drain 306, and length of the second gate 316 corresponding to the second source 318 is longer than length of the second gate 316 corresponding to the third source 320. Therefore, when the second gate 316 receives the second control signal SCS generated from the pulse width modulation controller 114 (as shown in FIG. 1), a second current flowing through the drain 306 to the second source 318 is proportional to a third current flowing through the drain 306 to the third source 320. That is to say, a ratio of the second current to the third current is equal to a ratio of the length of the second gate 316 corresponding to the second source 318 to the length of the second gate 316 corresponding to the third source 320. That is to say, after the pulse width modulation controller 114 is started up, the power switch and the current detection unit are turned on when a voltage of the second control signal SCS is higher than a threshold voltage, resulting in the second current flowing through the drain 306 to the second source 318 and the third current flowing from the drain 306 to the third source 320; when the voltage of the second control signal SCS is lower than the threshold voltage, the power switch and the current detection unit are turned off. Because the third current is proportional to the second current (e.g. the second current is 100 times the third current), the pulse width modulation controller 114 can generate the second control signal SCS according to the third current to control turning-on and turning-off of the third current and the second current. In addition, compared to the prior art, because the second current flowing through the power switch does not flow through the current detection unit, negative voltage effect and noise generated by a parasitic inductor of the third source 320 and power loss of the current detection unit can be significantly reduced. In addition, the power switch and the current detection unit of the super high voltage device 300 can be the same structure. But, the present invention is not limited to the power switch and the current detection unit of the super high voltage device 300 being the same structure. That is to say, in another embodiment of the present invention, the power switch and the current detection unit of the super high voltage device 300 can be a resistor structure, or a composite structure composed of a metal-oxide-semiconductor field effect transistor and a resistor structure.

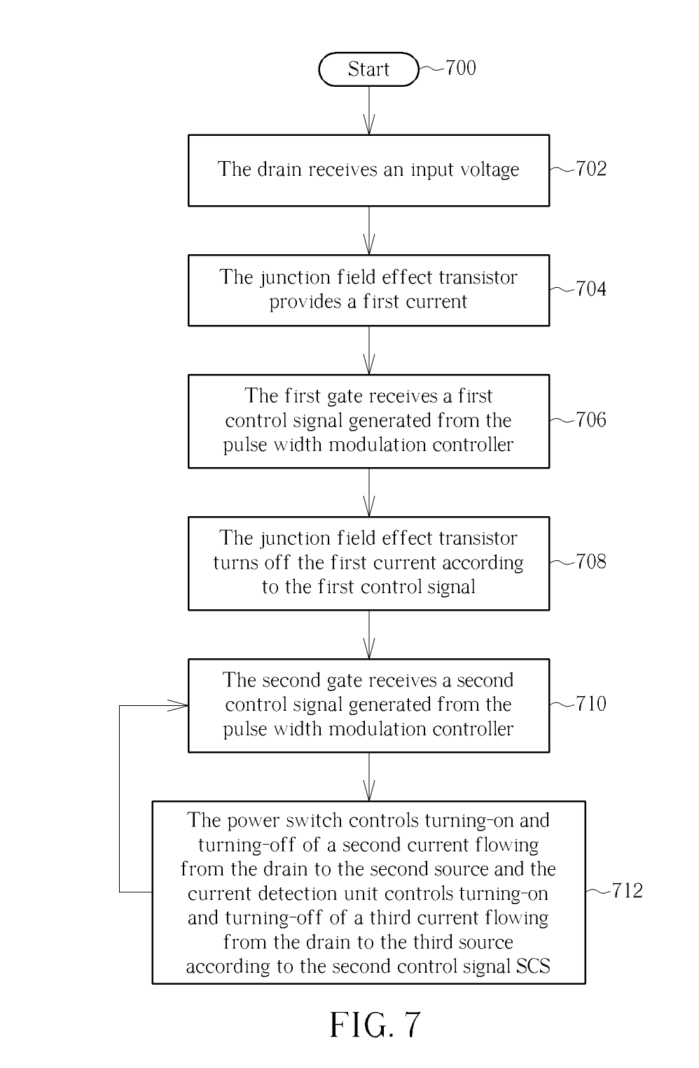

Please refer to FIG. 1 and FIG. 7. FIG. 7 is a flowchart illustrating method of operating a super high voltage device according to another embodiment. The method in FIG. 7 is illustrated using the super high voltage device 100 in FIG. 1. Detailed steps are as follows:

Step 700: Start.

Step 702: The drain 106 receives an input voltage VIN.

Step 704: The junction field effect transistor provides a first current.

Step 706: The first gate 102 receives a first control signal FCS generated from the pulse width modulation controller 114.

Step 708: The junction field effect transistor turns off the first current according to the first control signal FCS.

Step 710: The second gate 104 receives a second control signal SCS generated from the pulse width modulation controller 114.

Step 712: The power switch controls turning-on and turning-off of a second current flowing from the drain 106 to the second source 110 and the current detection unit controls turning-on and turning-off of a third current flowing from the drain 106 to the third source 112 according to the second control signal SCS; go to Step 710.

In Step 702, when the power conversion circuit 200 is started up, the power conversion circuit 200 can generate the input voltage VIN having the super high voltage level according to the alternating current voltage VAC. Then, the drain 106 receives the input voltage VIN. In Step 704, the junction field effect transistor (the first gate 102, the drain 106, and the first source 108) of the super high voltage device 100 can provide the first current (that is, the startup current of the pulse width modulation controller 114) to the pulse width modulation controller 114 to start up the pulse width modulation controller 114 before a voltage between the first gate 102 and the first source 108 is not equal to a pinch-off voltage. That is to say, when the power conversion circuit 200 is stared up, the power conversion circuit 200 can generate the input voltage VIN having the super high voltage level according to the alternating current voltage VAC. Meanwhile, the junction field effect transistor of the super high voltage device 100 can provide the first current to the pulse width modulation controller 114 to start up the pulse width modulation controller 114 according to the input voltage VIN having the super high voltage level. In Step 706, after the pulse width modulation controller 114 is started up, the pulse width modulation controller 114 can generate the first control signal FCS to the first gate 102. Then, in Step 708, the junction field effect transistor of the super high voltage device 100 can turn off the first current according to the first control signal FCS. That is to say, after the pulse width modulation controller 114 is started up, the junction field effect transistor is turned off to reduce power consumption of the super high voltage device 100 when the voltage between the first gate 102 and the first source 108 is equal to the pinch-off voltage. In Step 710, after the pulse width modulation controller 114 is started up, the pulse width modulation controller 114 can generate a second control signal SCS to the second gate 104, where the second control signal SCS is a pulse width modulation signal. In Step 712, when a voltage of the second control signal SCS is higher than a threshold voltage, the power switch (the second gate 104, the drain 106, and the second source 110) and the current detection unit (the second gate 104, the drain 106, and the third source 112) are turned on, resulting in the second current flowing from the drain 106 to the second source 110 and the third current flowing from the drain 106 to the third source 112; when the voltage of the second control signal SCS is lower than the threshold voltage, the power switch and the current detection unit are turned off. In addition, because the third current is proportional to the second current, the pulse width modulation controller 114 can generate the second control signal SCS to control turning-on and turning-off of the power switch and the current detection unit according to the third current. In addition, in another embodiment of the present invention, the pulse width modulation controller 114 can know the third current flowing through the current detection unit and the second current flowing through the power switch according to a voltage drop of the sensing resistor 118.

To sum up, the super high voltage device and the method of operating the super high voltage device utilize the junction field effect transistor (the first gate, the drain, and the first source) of the super high voltage device to generate the startup current of the pulse width modulation controller according to the input voltage. After the pulse width modulation controller is started up, the pulse width modulation controller can generate the second control signal to the second gate of the super high voltage device according to the third current flowing through the current detection unit (the second gate, the drain, and the third source) of the super high voltage device. Then, the power switch (the second gate, the drain, and the second source) of the super high voltage device can turn on and turn off the second current flowing through the power switch of the super high voltage device according to the second control signal, and the current detection unit can turn on and turn off the third current flowing through the current detection unit of the super high voltage device according to the second control signal because the third current is proportional to the second current. Therefore, compared to the prior art, the present invention has advantages as follows: first, because the super high voltage device is integrated with a high voltage startup function, a clock control chip having a requirement of the high voltage startup function does not need to be taped out to a fabrication plant for semiconductor manufacture having a super high voltage process; second, because the power switch of the super high voltage device has a low conductor impedance, the present invention can reduce conduction loss and heat generation of the super high voltage device; third, because the second current flowing through the power switch of the super high voltage device does not flow through the current detection unit of the super high voltage device, negative voltage effect and noise generated by a parasitic inductor of the third source and power loss of the current detection unit can be significantly reduced.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A super high voltage device, comprising:
a first gate for receiving a first control signal generated from a pulse width modulation controller;
a second gate for receiving a second control signal generated from the pulse width modulation controller;
a drain for receiving an input voltage;
a first source;
a second source; and
a third source;
wherein first current flowing from the drain to the first source varies with the first control signal and the input voltage, and the second control signal is used for controlling turning-on and turning-off of second current flowing from the drain to the second source and third current flowing from the drain to the third source, wherein the third current is proportional to the second current.

2. The super high voltage device of claim 1, wherein thickness of the first gate is the same as thickness of the second gate.

3. The super high voltage device of claim 1, wherein thickness of the first gate is greater than thickness of the second gate.

4. The super high voltage device of claim 1, wherein the input voltage is generated by a power conversion circuit.

5. The super high voltage device of claim 1, wherein the first current acts as startup current of the pulse width modulation controller.

6. A super high voltage device, comprising:
a substrate having a first conductivity type;
a first doped well having a second conductivity type, wherein the first doped well is formed on the substrate and has an extension portion;
a drain having the second conductivity type, wherein the drain is formed on the first doped well, and ion concentration of the drain is higher than ion concentration of the first doped well;
a second doped well having the first conductivity type, wherein the second doped well surrounds the first doped well outside the extension portion, and is formed on the substrate;
a first source having the second conductivity type, wherein the first source is formed on the extension portion, and ion concentration of the first source is higher than ion concentration of the first doped well;
a first field oxide formed on the first doped well outside the first source, the drain, and the second doped well;
a first gate formed between the drain and first source, and being located on the first field oxide;
a second gate formed partially on the first field oxide of the first doped well and formed partially on the second doped well;
a second source having the second conductivity type, wherein the second source is formed on the second doped well, and ion concentration of the second source is higher than ion concentration of the second doped well;
a third source having the second conductivity type, wherein the third source is formed on the second doped well, and ion concentration of the third source is higher than ion concentration of the second doped well; and
a base having the first conductivity type, wherein the base is formed on the second doped well, and ion concentration of the base is higher than ion concentration of the second doped well.

7. The super high voltage device of claim 6, wherein the first doped well, the drain, the second doped well, the first source, the second source, the third source, and the substrate are formed by a photolithography process and ion implantation.

8. The super high voltage device of claim 6, wherein the drain, the first source and the extension portion are located at the same axis.

9. The super high voltage device of claim 6, wherein the first conductivity type is P type, and the second conductivity type is N type.

10. The super high voltage device of claim 6, wherein the first conductivity type is N type, and the second conductivity type is P type.

11. The super high voltage device of claim 6, wherein the first field oxide is a field oxide fabricated by a Local Oxidation of Silicon (LOCOS).

12. The super high voltage device of claim 6, wherein the first gate and the second gate are polysilicon gates.

13. The super high voltage device of claim 6, further comprising:
a second field oxide formed on the second doped well between the third source and the base, and being a field oxide fabricated by a LOCOS.

14. The super high voltage device of claim 6, further comprising:
a third field oxide formed on the second doped well of a side of the base, and being a field oxide fabricated by a LOCOS.

15. The super high voltage device of claim 6, wherein length of the second gate corresponding to the second source is longer than length of the second gate corresponding to the third source.

16. The super high voltage device of claim 6, wherein thickness of the first gate is the same as thickness of the second gate.

17. The super high voltage device of claim 6, wherein thickness of the first gate is greater than thickness of the second gate.

18. A method of operating a super high voltage device, wherein the super high voltage device comprises a first gate, a second gate, a drain, a first source, a second source, and a third source, the method comprising:
receiving an input voltage;
providing first current, wherein the first current flows from the drain to the first source;
receiving a first control signal generated from a pulse width modulation controller;
turning off the first current according to the first control signal;
receiving a second control signal generated from the pulse width modulation controller; and
controlling turning-on and turning-off of second current flowing from the drain to the second source and third current flowing from the drain to the third source according to the second control signal.

19. The method of claim 18, wherein the third current is proportional to the second current.

20. The method of claim 18, wherein the first current acts as startup current of the pulse width modulation controller.
